(19) United States
(12) Patent Application Publication
(10) Pub. No.: US 2012/0263877 A1
(43) Pub. Date: Oct. 18, 2012

(54) CVD Reactor Having Gas Inlet Zones that Run in a Strip-Like Manner and a Method for Deposition of a Layer on a Substrate in a CVD Reactor of this Kind

(76) Inventors: Gerhard Karl Strauch, Aachen (DE); Martin Dauelsberg, Aachen (DE)

(21) Appl. No.: 13/391,561

(22) PCT Filed: Aug. 2, 2010
(86) PCT No.: PCT/EP2010/061174

§ 371 Date: Jul. 3, 2012

(30) Foreign Application Priority Data
Aug. 24, 2009 (DE) 102009043840.8

(51) Int. Cl. C23C 16/455; C23C 16/458

(52) U.S. Cl. 427/255.28; 118/728; 118/730

(57) ABSTRACT

The invention relates to a CVD reactor having a process chamber (1), the floor (3) of which is formed by a susceptor (2) for receiving substrates (4) to be coated with a layer and the ceiling (6) of which is formed by the underside of a gas inlet element (5) that has a multiplicity of gas inlet openings (13, 14) distributed uniformly over its entire surface, the gas inlet openings (13, 14) being divided into strip-like first and second gas inlet zones (11, 12) that run parallel to one another in a direction of extent, the gas inlet openings (13) of a first gas inlet zone (11) being connected to a common first process-gas feed line (9) for introducing a first process gas into the process chamber (1), the gas inlet openings (14) of a second gas inlet zone (12) being connected to a common first process-gas feed line (10), which is different from the first process-gas feed line (9), for introducing a second process gas into the process chamber (1), and the first and second gas inlet zones (11, 12) lying alternatingly alongside one another. The spacing (D) of a multiplicity of gas inlet openings (13, 14) of each gas inlet zone (11, 12) that lie side by side transverse to the direction of extent is to be approximately one quarter of the height (H) of the process chamber (1) and the width (W) of an individual gas inlet zone (11, 12) is to correspond approximately to the height (H).

The invention relates to a CVD reactor having a process chamber, the floor of which is formed by a susceptor for receiving substrates to be coated with a layer and the ceiling of which is formed by the underside of a gas inlet element that has a multiplicity of gas inlet openings distributed uniformly over its entire surface, the gas inlet openings being divided into strip-like or band-like first and second gas inlet zones that run parallel to one another in a direction of extent, the gas inlet openings of a first gas inlet zone being connected to a common first process-gas feed line for introducing a first process gas into the process chamber, the gas inlet openings of a second gas inlet zone being connected to a common first process-gas feed line, which is different from the first process-gas feed line, for introducing a second process gas into the process chamber, and the first and second gas inlet zones lying alternatingly alongside one another.

The invention furthermore relates to a method for depositing a layer on a substrate in a process chamber, the floor of the chamber being formed by a susceptor on which the substrate lies, and the ceiling of the chamber being formed by the underside of a gas inlet element that has a multiplicity of gas inlet openings distributed uniformly over its entire surface, the gas inlet openings being divided into strip-like or band-like first and second gas inlet zones that run parallel to one another in a direction of extent, the gas inlet openings of a first gas inlet zone being connected to a common first process-gas feed line, through which process-gas feed line a first process gas is introduced into the process chamber, the gas inlet openings of a second gas inlet zone being connected to a common second process-gas feed line, which is different from the first process-gas feed line, through which process-gas feed line a second process gas is introduced into the process chamber, and the first and second gas inlet zones lying alternatingly alongside one another.

A generic apparatus is described by U.S. Pat. No. 5,595,606. Within a reactor housing, there is in this case a susceptor, which is heated from beneath. One or more substrates are supported on the horizontal surface of the susceptor. The support surface for the substrate forms the floor of a process chamber. The ceiling of the process chamber is formed by the underside of a gas inlet element. This underside forms a gas inlet surface, which provides a multiplicity of nozzle-like gas inlet openings. The gas inlet openings are connected to feed lines, through which the various process gases can be introduced into the gas inlet openings. The gas inlet openings are assigned to strip-like first and second gas inlet zones that run parallel to one another, the first and second gas inlet zones alternating with one another. The first process gas is conducted into the process chamber exclusively through the first gas inlet zone and the second process gas is conducted into the process chamber exclusively through the second gas inlet zone, in each case with a carrier gas. The width of the gas inlet zone equates to the spacing of two neighboring gas inlet openings. The height of the process chamber is significantly greater than the spacing of two gas inlet zones.

WO 2008/032 910 A1 describes a CVD reactor in which the gas inlet element is able to introduce three different process gases into the process chamber. On the underside of the gas inlet element, there is a multiplicity of gas inlet openings which are in a line one after the other. Three strips lie alternatingly side by side, each strip having a single-line arrangement of gas outlet nozzles. Purge gas outlet openings are disposed alongside the single rows. One of these rows passes through the center of the circular gas inlet element and is neighbored by outlet openings for two reactive gases that are different from one another, so that the arrangement is assymetrical.

U.S. Pat. No. 4,880,163 describes a CVD reactor with a gas inlet element which has strip-like gas inlet zones, disposed side by side, for process gases that are different from one another.

U.S. Pat. No. 6,090,210 describes a CVD reactor with different gas inlet zones for process gases that are different from one another, the zones surrounding the center of a gas inlet element.

U.S. Pat. No. 5,500,256 describes gas inlet zones that run in the shape of spirals, here also the zone width equating to the direct spacing between two gas inlet zones that neighbor one another.

DE 10 2005 055 468 A1 describes a method for depositing layers in a CVD reactor. Here also, the process gases that are different from one another enter into the process chamber from gas inlet zones that are different from one another. Gas inlet elements for introducing process gases that are different from one another into a process chamber, an individual set of gas inlet nozzles being associated with each process gas, are also described in EP 1 118 691 A1, U.S. Pat. No. 6,086,677, U.S. 2004/0040502 A1, U.S. 2004/0191413 A1, U.S. 2006/0201428 A1 and U.S. 2007/0101929 A1.

Non-prepublished WO 2010/065695 A2 describes gas inlet strips disposed side by side which are formed as diffusers, in order to introduce process gases that are separated from one another into the process chamber.

A generic apparatus has a reactor housing, which is closed in a gastight manner against the environment and has, in its interior, a process chamber that has the shape of a circular cylinder, the disk-like floor of which is formed by a susceptor heated from beneath and the disk-like ceiling of which is formed by a likewise heatable gas inlet element. One or more substrates may lie on the substrate holder. The substrate holder may have a multiplicity of individual bearing disks, each of which carries one or more substrates, the bearing disks being driven in rotation on a gas cushion. The susceptor which is carried by a central pillar may be rotated about the axis of symmetry of the process chamber. A gaseous organometallic compound can be introduced into the process chamber through the first gas inlet zone, together with a carrier gas which may be hydrogen, nitrogen or a noble gas. In question here are for example TMGa, TMIn or TMAl. The second process gas that is introduced into the process chamber through the second gas inlet zone is a hydride, for example arsine, phosphine or ammonia. By means of these process gases, semiconductor layers are to be deposited on the surfaces of the substrate, which layers may consist of Ga, In, Al, P, As and N. By means of this apparatus, not only can III-V semiconductor layers be deposited, but also, by suitable selection of different starting materials, II-VI semiconductor layers. Furthermore, it is also possible to dope the deposited semiconductor layers by the addition of suitable, highly-diluted, alternative starting materials. The process gases introduced into the process chamber decompose pyrolytically. It would be optimal for the decomposition to take place only on the substrate surface. Since however the gas located within the process chamber above the susceptor also heats up by virtue of heat conduction or the like, predecompositions of the starting materials cannot be avoided. The products of predecomposition of the starting materials react with one another in a disadvantageous manner. At temperatures below for example 500° C., the predecomposition products form adducts. The adduct formation temperature depends on the composition of the process gases introduced into the process chamber and is in the range between 100° C. and 500° C. The adducts that form by the partial decomposition reduce not only the crystal quality of the deposited layers. By nucleus formation on the adducts and nucleations resulting from this, conglomerates of the starting materials or of their decomposition products may form, which are prevented by thermophoresis from a downward movement toward the substrate surface. This fraction of the very expensive starting materials, which is not available for crystal growth, is carried along by the gas flow to a gas outlet element, where it leaves the process chamber without having been used.

It is an object of the invention to provide arrangements by which the quality of the layer deposited and the efficiency of the coating process may be improved.

This object is met by the invention specified in the claims, wherein the apparatus is first and foremost improved to the effect that the width of the gas inlet zones is widened. A plurality of gas inlet openings now lie not only one after the other, but also alongside one another, so that strip-like or band-like gas inlet zones are formed, each gas inlet zone having a width which substantially equates to four times the spacing of two neighboring gas inlet openings. The gas inlet zones extend substantially over the entire width of the circular gas inlet element and have gas outlet openings that lie side by side transverse to the direction of extent. The gas inlet zones that extend near the center are the longest. The shortest gas inlet zones extend in the region of the periphery. The gas inlet zones, through which the process gases that are different from one another are introduced into the process chamber, lie preferably directly next to one another. In a preferred configuration of the invention, no further gas inlet openings through which a purge gas or the like is introduced into the process chamber, lie therefore between two gas inlet zones. The gas inlet openings of an individual gas inlet zone are fed from gas distribution chambers which are in turn connected by feed lines. The height of the process chamber corresponds to the width of the zone, thus likewise approximately to four times the spacing of gas inlet openings that neighbor one another. The gas inlet openings are arranged uniformly on the underside of the gas inlet element. They may be at the corner points of rectangles, in particular squares, or at the corner points of equilateral triangles. The layout of the alternating gas inlet zones that lie side by side in the manner of strips, is selected so that the center of the gas inlet surface that has a circular shape lies in a zone boundary. The axis of rotation also runs through this center, about which the susceptor, that has likewise a circular peripheral shape, is rotatable. The diameter of the gas inlet openings is approximately 0.6 mm±10%. Their spacing, i.e. the edge length of the square at the corner points of which the gas inlet openings are located, is approximately 2.6 mm±10%, so that there results an optimal process chamber height of approximately 11.0 mm±10%. The diameter of the susceptor and of the gas inlet surface and thus of the process chamber is greater than 300 mm. Typically its diameter is approximately 32 cm. The process carried out in the CVD reactor is characterized in that in each case a first process gas is introduced into the process chamber through the first gas inlet zones and in each case a second process gas is introduced into the process chamber through the second gas inlet zones, in each case together with a carrier gas, the first process gas containing one of the aforementioned organometallic compound and the second process gas containing one of the aforementioned hydrides. The carrier gas may be hydrogen, nitrogen or a noble gas. In order to supply the hydride in an effective excess to the growth surface, the deposition process is carried out under total pressures of 500 mbar to 1,000 mbar and preferably at about 600 mbar. The mass flow through the gas inlet openings into the process chamber is selected so that in the upper half of the process chamber volume, the flow relaxes, and the process gases mix, for them to be transported to the substrate surface substantially by diffusion in the lower half of the process chamber. A uniform coating is achieved by virtue of the homogenisation arising from the continual rotation of the susceptor. There are no local deviations from the average crystal composition, which is not to be tolerated. In the upper half of the process chamber volume and in the upper regions of the lower half of the process chamber volume, the process gases that are different from one another come into contact substantially only in the region of the zone boundary. Only in this region can the adducts form, that are mentioned at the beginning and are to be avoided. The harmful loss mechanism by way of cluster formation, mentioned at the beginning, cannot however be fully avoided by the measures according to the invention, but can be significantly reduced. It is possible to do without purge zones disposed between the individual gas inlet zones. The process gas introduced into the process chamber in the respective central region of a zone, i.e. through the two inner gas inlet openings of the respective gas inlet zone, meets the respective other process gas for the first time at the boundary toward the lower region of the process chamber. Up to this, the respective process gas and in particular the organometallic components have in fact decomposed into one or more products of decomposition. The remaining reaction time is however significantly reduced because of the shortened path to the substrate. Model calculations have shown that this reaction time is of very great importance to the formation of adducts and clusters. If the reaction time is reduced by suitable measures, clustering and thus the harmful loss mechanism is inevitably also reduced. The surface temperature of the susceptor may therefore be above 1,000° C. and in particular 1,100° C. throughout. The diffusion length of the precursor introduced into the process chamber is approximately half the height of the process chamber for the process conditions, i.e. for a total pressure of at least 500 mbar and for gas temperatures of at least 500° C. The process chamber height is therefore selected so that it equates to twice the diffusion length.

An exemplary embodiment of the invention will be described below with reference to accompanying drawings in which:

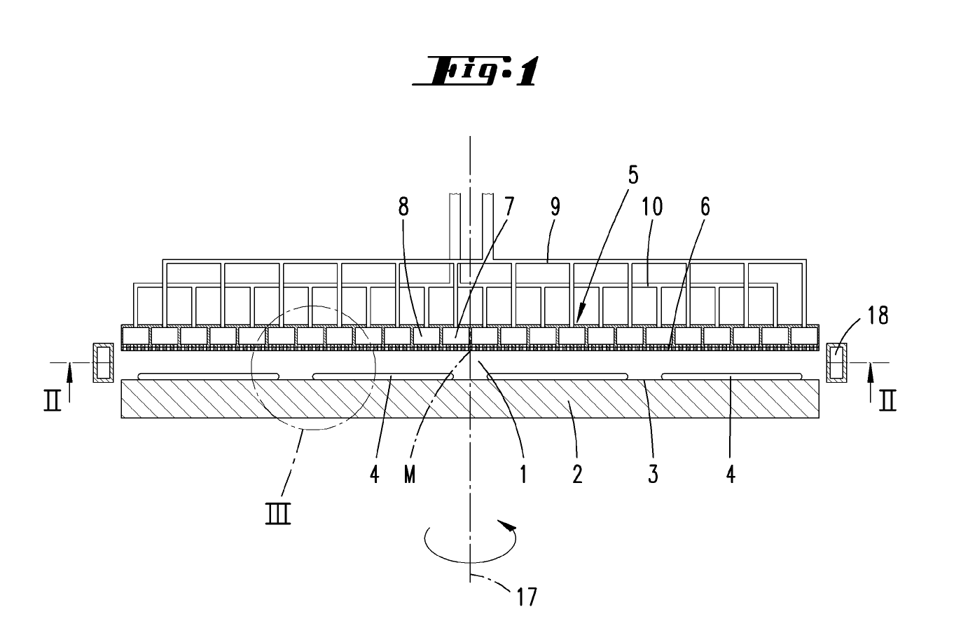

FIG. 1 shows schematically the cross-section through a process chamber disposed within a reactor housing,

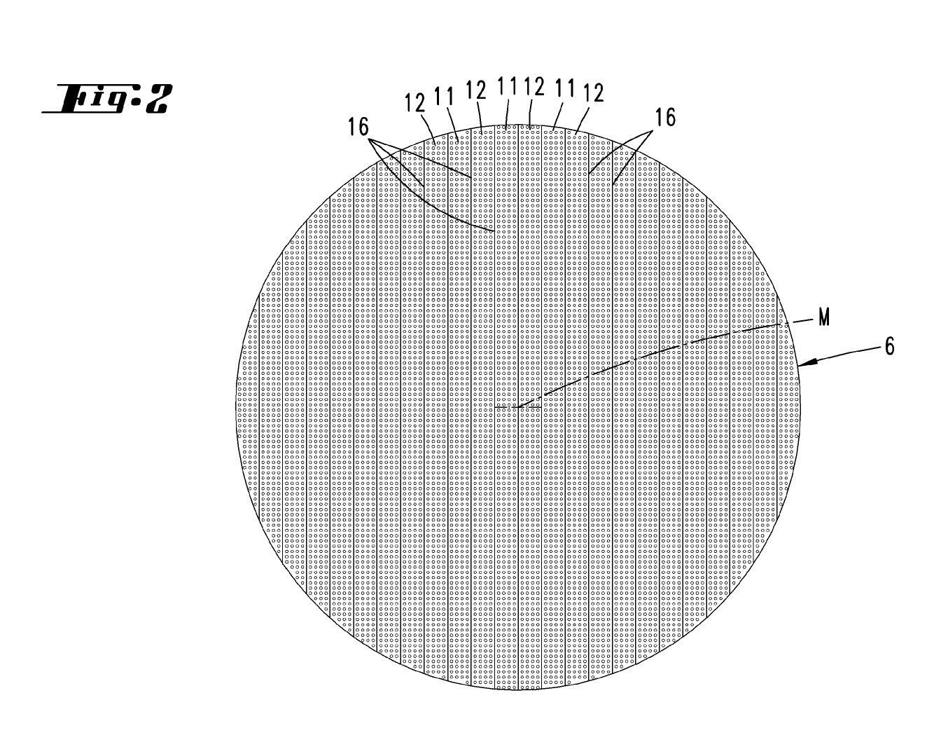

FIG. 2 shows a view from below of the gas inlet surface of the gas inlet element 5,

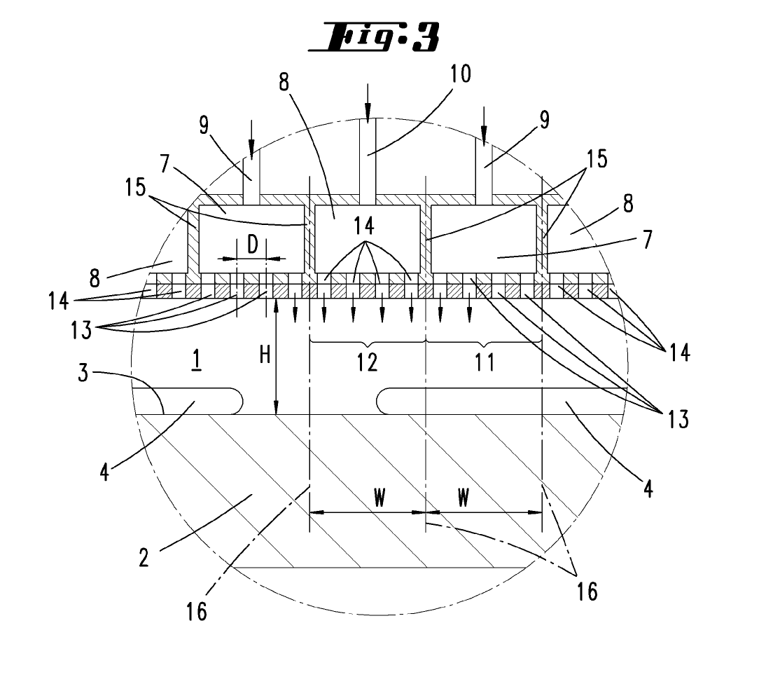

FIG. 3 shows an enlarged portion III-III in FIG. 1 of the cross-section of the process chamber, and

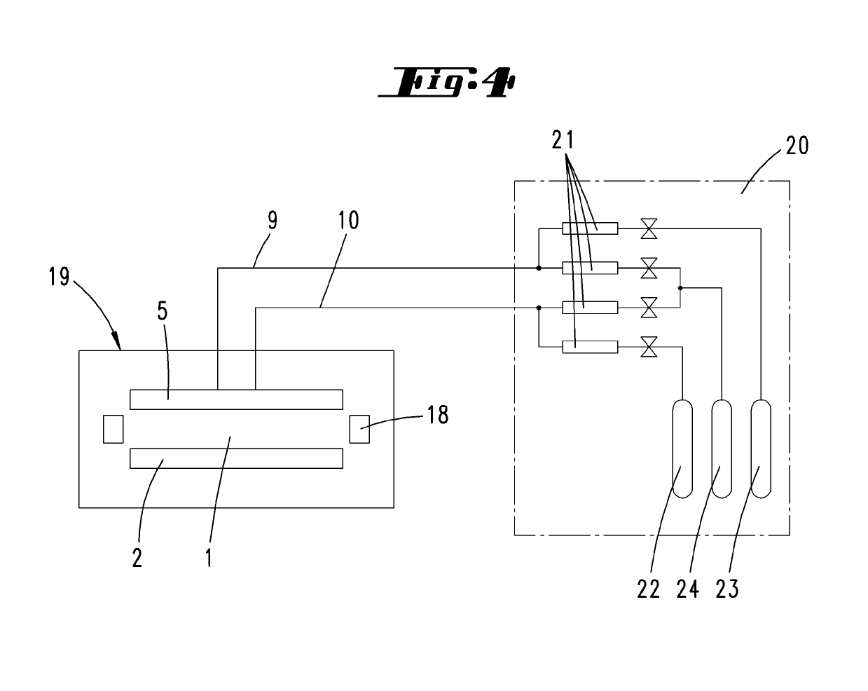

FIG. 4 shows the schematic layout of a CVD reactor that has a gas mixing system.

FIG. 4 shows the schematic layout of a CVD reactor according to the invention in which the method according to the invention can be carried out. The reactor housing 19 indicated by the reference numeral 19 encapsulates the process chamber 1 against the environment in a gastight manner, the process chamber extending between a gas inlet element 5 and a susceptor 2. The process gases are introduced into the process chamber 1 by way of at least two feed lines 9, 10. The carrier gas, carrying process gases, is brought out of the process chamber 2 along with reaction products through a gas outlet annulus 18 and brought out of the CVD reactor housing 19 through discharge lines that are not shown.

The first feed line 9 and the second feed line 10 are supplied by a gas mixing system 20. The gas mixing system 20 has a reservoir for an organometallic component, which forms a first process gas. This may be TMGa, TMIn or TMAl. The second process gas, which is held in the reservoir 22, is a hydride, for example arsine, phosphine or ammonia. The reservoirs 23 holding the organometallic components may have the form of a washing bottle through which a carrier gas flows. The carrier gas, which is stored in particular centrally in the reservoir 24, is in the form of hydrogen, nitrogen or a noble gas. The two process gases together with the carrier gas are fed in a metered manner into the respective feed line 8, 9 by means of mass-flow controllers 21 and valves arranged upstream or downstream.

As will be apparent from FIG. 1, the respective first feed lines 9 and second feed lines 10 branch out in a multiple manner in such a way that a multiplicity of first distribution chambers 7 of the gas inlet element 5 are supplied through a first feed line 9 with a first process gas and a multiplicity of second distribution chambers 8 of the gas inlet element 5 are supplied through a second feed line 10 with a second process gas.

The gas inlet element has a circular shape in plan view and an underside 6, which has a multiplicity of gas inlet openings 13, 14 which are distributed uniformly over its surface. As will be apparent from FIG. 2, the individual gas inlet openings 13, 14 lie at the corner points of notional squares.

The gas inlet openings 13, 14 are associated with gas inlet zones 11, 12 that are different from one another. Two different kinds of gas inlet zones 11, 12 are provided, with which there are respectively individually associated a first distribution chamber 7 and a second distribution chamber 8. Through the gas inlet zones 11 of the first kind, there enters into the process chamber 1 exclusively the first process gas that is dissolved in a carrier gas. Through the gas inlet zones of the second kind, there enters into the process chamber 1 exclusively the second process gas together with a carrier gas. The gas inlet zones 11, 12 of the first and second kind are provided in the manner of strips or bands. The gas inlet zones 11, 12 alternate with one another in such a way that up to the two most outwardly located gas inlet zones, each gas inlet zone 11 of the first kind is neighbored by two gas inlet zones 12 of the second kind and each gas inlet zone 12 of the second kind is neighbored by two gas inlet zones 11 of the first kind. The zone boundaries 16 between two gas inlet zones 11, 12 that are different from one another run underneath dividing walls 15, which separate from another the two distribution chambers 7, 8 that are different from one another and likewise run alongside one another in the manner of a strip or band.

The gas inlet zones 11, 12 extend, running parallel to one another, from one edge of the gas inlet surface 6 of the gas inlet element 5 without interruption right up to the opposite edge of the gas inlet surface 6 of the gas inlet element 5. In the course of this, the dividing walls 15 are arranged so that one dividing wall and the zone boundary 16 defined by this wall pass through the center M of the gas inlet surface 6. The center M is therefore flanked by two gas inlet zones 11, 12 that are different from one another, these gas inlet zones 11, 12 being the longest inlet zones. The two shortest gas inlet zones 11, 12 are at the outermost edge of the gas inlet surface 6.

The diameter of the gas inlet openings 13 of the first kind and the gas inlet openings 14 of the second kind, the openings being configured to be identical to one another, is approximately 0.6 mm. The gas inlet openings 13, 14 are spaced from one anther by approximately 2.6 mm. The length of the gas inlet zones 11, 12 varies. Their width is however the same. The width of the gas inlet zones 11, 12 is selected so that four gas inlet openings 13, 14 of an individual gas inlet zone 11, 12 lie side by side. The width W of a gas inlet zone 11, 12 thus equates to four times the spacing D between two gas inlet openings 13, 14. The width of an individual gas inlet zone 11, 12 is substantially defined by the number of the gas inlet openings 13, 14 that lie side by side transverse to the direction of extent of the gas inlet zones 11, 12.

It is regarded as advantageous for gas inlet zones 11, 12, through which the process gases that are different from one another flow into the process chamber, to be directly adjacent to one another. It is not necessary for purge gas openings, through which an inert gas is introduced into the process chamber, to be provided between the gas inlet openings of the first kind and gas inlet openings of the second kind.

The susceptor 2, which is arranged parallel to the gas inlet element 5, has an upper surface 3, on which a multiplicity of substrates 4 is disposed. The substrates 4 may be supported there in the densest possible packing on the circular susceptor 2 that consists of graphite. The susceptor 2 may be driven in rotation by drive means, not shown, about an axis of rotation 17, which passes through the center M of the gas inlet element 5. The individual substrates 4 may also lie on supporting disks that are driven in rotation.

The height H of the process chamber 1, i.e. the spacing between the floor 3 and the ceiling 6, is selected so that the process gases exiting out of the two inner openings 13, 14 of the respective gas inlet zones 11, 12 enter initially into the lower half and preferably come into contact with the respective other process gas only in the lower region of the lower half of the process chamber volume 1. Within the upper half of the process chamber 1, there mix with one another therefore only the process gases exiting out of the gas inlet openings 13, respectively adjacent to the zone boundary 16. Formation of adducts is thus limited there to the immediate region around the zone boundary 16. It is optimal for the height H of the process chamber 1 to equate to twice the diffusion length of the process gas dissolved in the carrier gas. The total pressure within the process chamber is in the range between 500 mbar and 1,000 mbar and preferably is approximately 600 mbar. The substrate temperature is approximately 1,100° C. The surface temperature of the process chamber ceiling 6 is somewhat more than 500° C. or 600° C. This temperature depends on the composition of the process gases, on which composition the adduct formation temperature depends, this being in the range from 500° C. to 600° C. The temperature of the process chamber ceiling 6 is however held below the growth-temperature limit for kinetic growth, this being in the range between 850° C. and 900° C., depending on the process gases.

In order to meet these requirements, the height H of the process chamber 1 equates approximately to the value of the width W of the gas inlet zones 11, 12. All of the gas inlet zones 11, 12 have the same width W of approximately 10.4 mm. In the exemplary embodiment, the process chamber has a height of 11 mm. The diameter of the process chamber, which is surrounded by a gas outlet annulus 18, is approximately 32 cm. There results thereby a reactor volume of approximately 900 cm³. The volume in which adducts can form in the upper half of the process chamber is reduced to about 40 cm³. But adducts can also form in the central region of the gas inlet zones 11, 12, since a through mixing is desired there in the lower region of the process chamber volume. However, the adducts forming there have only a short path length as far as the surface of the substrate 4 and thus only a very short reaction time, so that clustering is effectively reduced.

All features disclosed are (in themselves) pertinent to the invention. The disclosure content of the associated/accompanying priority documents (copy of the prior application) is also hereby included in full in the disclosure of the application, including for the purpose of incorporating features of these documents in claims of the present application. The subsidiary claims characterize, in their optionally dependent formulation, independent inventive development of the prior art, in particular for the purpose of filing divisional applications based on these claims.

1. A CVD reactor comprising a process chamber (1), a floor (3) of which is formed by a susceptor (2) for receiving substrates (4) to be coated with a layer and a ceiling (6) of which is formed by an underside of a gas inlet element (5) that has a multiplicity of gas inlet openings (13, 14) distributed uniformly over its entire surface, the gas inlet openings (13, 14) being divided into strip-like first and second gas inlet zones (11, 12) that run parallel to one another in a direction of extent, the gas inlet openings (13) of the first gas inlet zones (11) being connected to a common first process-gas feed line (9) for introducing a first process gas into the process chamber (1), the gas inlet openings (14) of the second gas inlet zones (12) being connected to a common second process-gas feed line (10), which is different from the first process-gas feed line (9), for introducing a second process gas into the process chamber (1), and the first and second gas inlet zones (11, 12) lying alternatingly alongside one another, each first and second gas inlet zone (11), (12) having a multiplicity of gas inlet openings (13, 14) that lie side by side transverse to the direction of extent spacing (D) of two directly neighboring gas inlet openings (13), (14) being approximately one quarter of a height (H) of the process chamber (1) and a width (W) of an individual gas inlet zone (11, 12) corresponding approximately to the height (H).

2. A CVD reactor according to claim 1, characterized in that the ceiling (6) and the floor (3) have a substantially circular shape and the susceptor (2) is rotatable about an axis (17) of rotation.

3. A CVD reactor according to claim 2, characterized in that a zone boundary (16) of a first gas inlet zone (11) and of a second gas inlet zone (12) runs through a center (M) of a gas inlet surface of the gas inlet element (5), through which center (M) there runs the axis (17) of rotation of the susceptor.

4. A CVD reactor according to claim 1, characterized in that the spacing of the outlet openings (13, 14) that lie side by side on a line in the manner of a row is approximately 2.6 mm.

5. A CVD reactor according to claim 1, characterized in that the height (H) of the process chamber (1) is approximately 11 mm.

6. A CVD reactor according to claim 1, characterized in that a diameter of the process chamber (1) is greater than 300 mm.

7. A method for depositing a layer on a substrate in a process chamber (1), floor (3) of the chamber being formed by a susceptor (2) on which the substrate (4) lies, and a ceiling (6) of the chamber being formed by an underside of a gas inlet element (5) that has a multiplicity of gas inlet openings (13, 14) distributed uniformly over its entire surface, the gas inlet openings (13, 14) being divided into strip-like first and second gas inlet zones (11, 12) that run parallel to one another in a direction of extent, the gas inlet openings (13) of the first gas inlet zones (11) being connected to a common first process-gas feed line (9), through which process-gas feed line (9) a first process gas is introduced into the process chamber (1), the gas inlet openings (14) of the second gas inlet zones (12) being connected to a common second process-gas feed line (10), which is different from the first process-gas feed line (9), through which process-gas feed line (10) a second process gas is introduced into the process chamber (1), the first and second gas inlet zones (11, 12) lying alternatingly alongside one another, characterized in that for a spacing (D) of the gas inlet openings (13, 14) from one another, a height (H) of the process chamber (1), a width (W) of an individual gas inlet zone (11, 12) and a total pressure in a range between 500 mbar and 1,000 mbar, a mass flow rate of a carrier gas introduced into the process chamber (1) through the respective gas inlet zones (11, 12) together with the process gases is selected so that a thorough mixing of the first and second process gases that are different from one another takes place only in a lower half of the process chamber (1), for which the spacing (D) of a multiplicity of gas inlet openings (13, 14) that are assigned to a common gas inlet zone and lie side by side transverse the direction of extent is approximately one quarter of a height (H) of the process chamber and a width (W) of an individual gas inlet zone (11, 12) corresponds approximately to the height (H).

8. A method according to claim 7, characterized in that the first process gas is an organometallic compound, in particular TMIn, TMGa or TMAl.

9. A method according to claim 7, characterized in that the second process gas is a hydride, in particular arsine, phosphine or ammonia.

10. A method according to claim 7, characterized in that the ceiling (6) that has the gas inlet openings (13, 14) has a temperature that lies above an adduct formation temperature of the first and second process gases.
